(19) United States
(12) Patent Application Publication
(10) Pub. No.: US 2011/0006409 A1
(43) Pub. Date: Jan. 13, 2011

(54) NICKEL-TITANUM CONTACT LAYERS IN SEMICONDUCTOR DEVICES

(76) Inventors: Michael D. Gruenhagen, Salt Lake City, UT (US); James J. Murphy, South Jordan, UT (US); Suku Kim, South Jordan, UT (US); Jim Pierce, Sandy, UT (US); William S. Beggs, Salt Lake City, UT (US); Robert J. Purtell, West Jordan, UT (US)

Correspondence Address: KENNETH E. HORTON;KIRTON & MCCONKLE, 60 EAST SOUTH TEMPLE, SUITE 1800, SALTLAKE CITY, UT, 84111, US

(21) Appl. No.: 12/501,849

(22) Filed: Jul. 13, 2009

(51) Int. Cl. H01L 23/498; H01L 23/495

(52) U.S. Cl. 257/666; 257/754; 257/737; 257/E23.031; 257/E23.072

(57) ABSTRACT

Semiconductor devices containing nickel-titanium (NiTi or TiNi) compounds (or alloys) and methods for making such devices are described. The devices contain a silicon substrate with an integrated circuit having a drain on the backside of the substrate, a TiNi contact layer contacting the drain on the backside of the substrate, a soldering layer on the contact layer, an oxidation reducing layer on the soldering layer, a solder bump on the soldering layer, and a lead frame attached to the solder bump. The combination of the Ti and Ni materials in the contact layer exhibits many features not found in the Ti and Ni materials alone, such as reduced backside on-resistance, ability to form a silicide with the Si substrate at lower temperatures, reduced wafer warpage, increased ductility for improved elasticity, and good adhesion properties. Other embodiments are described.

### FIELD

This application relates generally to semiconductor devices and methods for making such devices. More specifically, this application nickel-titanium (NiTi or TiNi) alloys that can be used in contact layers underlying soldering layers in semiconductor devices.

### BACKGROUND

Semiconductor devices containing integrated circuits (ICs) are used in a wide variety of electronic apparatus. The IC devices (or chips) comprise a miniaturized electronic circuit that has been manufactured in the surface of a substrate of semiconductor material. The circuits are composed of many overlapping layers, including layers containing dopants that can be diffused into the substrate (called diffusion layers) or ions that are implanted (implant layers) into the substrate. Other layers are conductors (polysilicon or metal layers) or connections between the conducting layers (via or contact layers).

IC devices can be fabricated in a layer-by-layer process that uses a combination of many steps, including imaging, deposition, etching, doping and cleaning. Silicon wafers are typically used as the substrate and photolithography is used to mark different areas of the substrate to be doped or to deposit and define polysilicon, insulators, or metal layers. One of the latter steps in the semiconductor fabrication process forms the electrical connections between the circuitry and the other electrical components in the electronic apparatus of which the IC chip is a part. While older technology utilized wire bonding, newer technology includes flip chip bonding processes where the active side of the IC chip is bonded to an electrical circuit of the printed circuit board (PCB) through solder bumps deposited either on the IC chip or the PCB.

### SUMMARY

This application relates to semiconductor devices containing nickel-titanium (NiTi or TiNi) compounds (or alloys) and methods for making such devices. The devices contain a silicon substrate with an integrated circuit having a drain on the backside of the substrate, a TiNi contact layer contacting the drain on the backside of the substrate, a soldering layer on the contact layer, an oxidation prevention layer on the soldering layer, a solder bump on the soldering layer, and a lead frame attached to the solder bump. The combination of the Ti and Ni materials in the contact layer exhibits many features not found in the Ti and Ni materials alone, such as reduced backside on-resistance, ability to form a silicide with the Si substrate at lower temperatures, reduced wafer warpage, increased ductility for improved elasticity, and good adhesion properties.

### BRIEF DESCRIPTION OF THE DRAWINGS

The following description can be better understood in light of the Figures, in which:

FIG. 1 shows some embodiments of methods for forming a semiconductor device containing a TiNi contact layer with a soldering layer;

FIG. 2 depicts some embodiments of methods for forming a semiconductor device containing a TiNi contact layer with an oxidation prevention layer, soldering layer, and solder ball;

FIG. 3 shows some embodiments of methods for forming a semiconductor device containing a TiNi contact layer with a lead frame attached to a solder bump.

The Figures illustrate specific aspects of the semiconductor devices and methods for making such devices. Together with the following description, the Figures demonstrate and explain the principles of the methods and structures produced through these methods. In the drawings, the thickness of layers and regions are exaggerated for clarity. It will also be understood that when a layer, component, or substrate is referred to as being “on” another layer, component, or substrate, it can be directly on the other layer, component, or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the devices and associated methods of making and using the devices can be implemented and used without employing these specific details. Indeed, the devices and associated methods can be placed into practice by modifying the illustrated devices and associated methods and can be used in conjunction with any other apparatus and techniques conventionally used in the industry. For example, while the description below focuses on methods for making for semiconductor devices in the IC industry, it could be used in and applied to other electronic devices like optoelectronic devices, solar cells, MEMS structures, lighting controls, power supplies, and amplifiers.

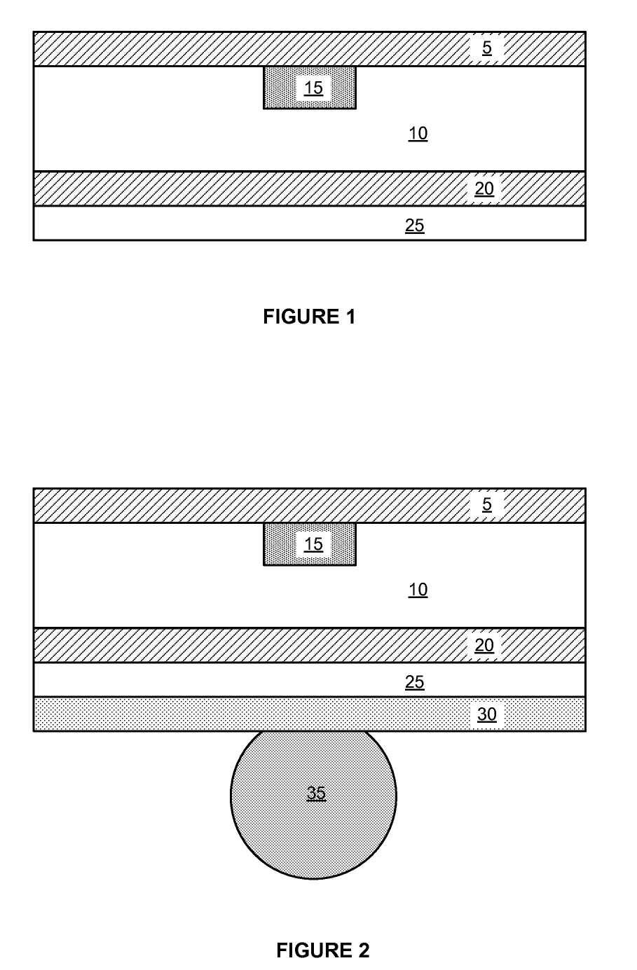

Some embodiments of the semiconductor devices and methods for making such devices are shown in FIGS. 1-3. In these embodiments, the methods for making the semiconductor devices begin by providing a substrate 10, as shown in FIG. 1. The substrate 10 may be made of any suitable semiconductor material. Some non-limiting examples of such materials may include silicon, gallium arsenide, silicon carbide, gallium nitride, silicon and germanium, and combinations thereof. In some embodiments, the substrate 10 comprises a silicon wafer with an epitaxial layer of Si deposited thereon. The silicon and/or the epitaxial layer can be undoped or doped with any known dopant, including boron (B), phosphorous (P) and arsenic (As).

Next, as known in the art, any known integrated circuit (IC) 15 can be formed in or on the substrate 10 using any known processing. Some non-limiting examples of these IC devices may include logic or digital IC devices, linear regulators, audio power amplifiers, LDO, driver IC, diodes, and/or transistors, including zener diodes, schottky diodes, small signal diodes, bipolar junction transistors (“BJT”), metal-oxide-semiconductor field-effect transistors (“MOSFET”), insulated-gate-bipolar transistors (“IGBT”), and insulated-gate field-effect transistors (“IGFET”). In some embodiments, the IC device 15 comprises a trench MOSFET device that can be made using any process known in the art. In other embodiments, the IC device 15 comprises a double-diffused metal-oxide-semiconductor (DMOS) device. In yet other embodiments, the IC device 15 comprises any semiconductor device containing a backside drain contact.

In some embodiments, a gate layer 5 has been formed on the upper surface of the substrate 10. The gate layer 5 is connected to the IC device 15 and serves as the gate for the IC device. In these embodiments, the gate layer 5 can be made of any conductive material such as Al, Si, polysilicon, silicon/nickel silicide, or silicon/cobalt silicide and can be made by any process known in the art. In some instances, further processing such as forming an interconnect (not shown) or forming a gate pad (not shown) can be performed on the upper surface of the gate layer 5 as known in the art. These steps on the front side of the wafer are used as part of the processing to manufacture the completed semiconductor device.

Next, the backside of the substrate 10 is thinned using any known process in the art. The backside of the substrate 10 can be thinned using any known polishing or grinding process. In some embodiments, the backside is thinned by providing a tape or carrier wafer on the gate transistor or upper side of the substrate 10 to operate as a support, grinding the backside using a diamond abrasive wheel, removing the tape from the front side, and then performing a stress relief etch (SRE) process using a spin etching tool, such as those made by the SEZ Group or Materials and Technologies Corporation. In some embodiments, the substrate 10 can be thinned to a thickness ranging from about 400 to about 10 μm. In other embodiments, the substrate 10 can be thinned to a thickness just below the active gate transistor structure of the dopant-activated source, channel and drain regions.

Then, a contact layer 20 can be formed on the backside of the substrate, as shown in FIG. 1, so that it is connected to the drain of the IC device 15. The contact layer 20 operates as silicon-to-metal interface or adhesion layer between the substrate 10 and the to-be-formed soldering metal layer (as described herein). Conventional contact layers have been formed using Ti, Al, Cr, Au, or Ni.

In some embodiments, the contact layer 20 can be formed as a TiNi compound or alloy. The amount of Ni in the alloy can be any amount that provides the physical characteristics described herein. In other embodiments, the amount of Ni in the alloy can range from about 0.5 to about 95.5 wt %. In still other embodiments, the TiNi layer is Nitinol which can contain approximately 50 to 55.6 wt % Ni. In even other embodiments, the TiNi layer contains approximately 51 wt % Ni (Ti₄₉Ni₅₁) since this particular formulation has very elastic ductile properties and is therefore less likely to experience brittle fractures. The Ti₄₉Ni₅₁ formulation has a Young's Modulus of elasticity ranging from about 28 to about 75 GPA which can provide the ability to substantially absorb changes that can be induced during thermal expansion and contraction. When it is used, the temperature of the semiconductor device increases and the metal layers expand more than the silicon in the substrate. Conversely, when the device is turned off, the device cools and the metal layers and the silicon contract at different rates. This mismatch in the thermal expansion and contraction rate needs to be absorbed by an elastic material that is placed between the metal and silicon or else cracks can develop in the interface between the silicon and the metal connection. Historically, elastic materials like solders have been used to help with this problem. Thus, the use of Ti/Ni alloys can also provide extra elastic strength to help hold the interconnection of the silicon and the metal together.

This ductile property is a feature that TiNi provides that neither Ti nor Ni exhibit. Ti and Ni metals by themselves are not very ductile materials since the Young's Modulus of elasticity for Ti is about 116 GPA and for Ni is about 200 GPA. Thus, Ti and Ni metals alone exhibit hard brittle properties. The result is that both metals are susceptible to cracking under fatique and stress conditions while the TiNi alloy will absorb the stress better and hold together.

The combination of the Ti and Ni materials in the contact layer 20 exhibits many other features that are not found in the Ti and Ni materials alone. Conventional contact layers typically contained either Ti or Ni, but not both. Contact layers containing Ti experienced problems during the formation of a silicide between it and the silicon substrate when Al is used on the front side of the wafer. The titanium silicidization process requires temperatures of about 630° C., which are above the melting point of Al. In some instances, the upper limit for Al front-side wafers can be closer to 480° C. because the Al becomes so soft it can be susceptible to sticking to the handler surfaces of automated equipment, especially robot paddles, that are typically used in the manufacturing processes. Ni, however, does not exhibit similar problems during the silicidization process because nickel forms silicides at temperatures between 350 to 400° C., well below the melting point of Al on the front side of the wafer.

Another problem with contact layers containing layers of only Ti or Ni is the lack of corrosion resistance of the Ni layer. It is known that Ni layers can continue while Ti layers exhibit the ability self passivate as a TiO₂ material. An improved corrosion resistance is becoming more important because it can reduce or prevent corrosion-induced degradation, especially since semiconductor devices are increasingly being made without plastic mold encapsulation (i.e., wafer level chip scale packages [WLCSP]). But by combining the two metals into one alloy, it becomes possible to make a surface-rich passivating TiO₂ outer surface over the Ti/Ni alloy, thereby providing a passivation layer for environmental protection.

Another problem with contact layers containing only Ti is the adhesion of the layer. Ti exhibits a poor adhesion between the Si substrate and overlying metal layers when it is exposed to boron-doped substrates. On the other hand, Ni exhibits good adhesion properties between boron containing Si substrates and overlying metal layers. As well, Ni does not form a brittle compound when it reacts with the boron that is contained as a dopant in the substrate 10.

At the same time, contact layers only containing Ni have also experienced problems. First, pure Ni silicides have the potential to highly warp the underlying Si substrate, thereby preventing easy manufacturing and causing performance degradation. TiNi materials do not suffer the same problem because they have a mixture of Ti and Ni materials. Indeed, by incorporating varying amounts of Ti with the Ni, the degree to which the underlying substrate is warped can be modified. Thus, the stress on the wafer can be adjusted by varying the amount of Ti (and therefore Ni) used in the contact layer.

Another problem with contact layers containing just Ni is the adhesion in the presence of native oxides which can form on the backside of the substrate 10 when the Si is exposed to oxygen. Nickel can be a poor adhesion material when it contacts native oxides. Titanium, however, does not suffer from the same defects because it exhibits good adhesion properties when contacting native oxides.

In some instance, the TiNi alloys can contain small to negligible amounts of other metals. In the embodiments where the TiNi alloys are sputter deposited, the sputtering process sometimes use Cu-containing backing plates. So a small level of Cu (<0.5 wt %) in the TiNi alloy can occur and can even sometimes be desired. In other embodiments, the TiNi alloy could contain negligible amounts of Mo or Ag, depending on how the TiNi alloy is formed.

The TiNi material in the contact layer 20 can be formed by any process known in the art. In some embodiments, the TiNi materials can be formed by a chemical vapor deposition (CVD) process or by a metal co-evaporation process. In other embodiments, a physical vapor deposition (PVD) or sputtering process using either a NiTi target or two targets (a Ti target and a Ni target) can be performed until the desired thickness of the TiNi alloy layer is formed. The thickness of the TiNi contact layer 20 can range from about 0.01 to about 10 μm. In some embodiments, the thickness can range from about 0.1 to about 3 μm.

Then, a heating process can be performed to form a silicide between the contact layer 20 and the silicon in the substrate 10. Silicide formation is possible at this stage because the contact layer 20 is not exposed to an oxygen atmosphere that would prevent adhesion of the next soldering layer. In some embodiments, the silicide formation process uses a thermal process to partially melt the Ni in the contact layer and react it with the silicon in the substrate 10 to form a Ni silicide. The thickness of the silicide can range from about 0.01 to about 8 μm and in some embodiments can range from about 0.02 to about 0.05 μm. The thermal process heats the silicon/Ni surface to a temperature ranging from about 350° C. to about 425° C. for a sufficient period of time to create a metal silicide that forms an ohmic contact with the silicon in the substrate 10. The heating process can be performed in any atmosphere containing negligible or no amounts of oxygen, such as an atmosphere containing N₂, Ar, He, inert gases, or combinations thereof. The heating can be performed by convection heating, conduction heating, laser anneal, or by microwave heating. In other embodiments, this silicidization can be performed after the deposition of the oxidation prevention layer. In these other embodiments, the oxygen exposure is not as an important consideration.

Next, a soldering layer 25 can be formed on the contact layer 20. The soldering layer 25 operates to react with Sn in the solder as well as act as a diffusion barrier layer for the latter-deposited solder. The soldering layer 25 can comprise any metal that forms a metal Sn intermetallic layer under soldering conditions of about 150 to 400° C. in an inert or reducing gas atmosphere (and sometimes a flux acid can be used to activate the reaction). Accordingly, in some embodiments, the soldering layer 25 can comprise substantially pure Ni, NiV (containing 7 wt % V, sometimes designated as Ni₉₃V₇), Cu, Si doped Ni, or combinations thereof. The soldering layer 25 can be formed using any known deposition process, including a CVD process, an evaporation process, or a PVD sputtering process. The deposition of the soldering layer can be performed in any atmosphere containing negligible or no amounts of oxygen (an oxygen-free atmosphere), such as an atmosphere containing He, N₂, Ar, inert gases, or combinations thereof. As much as feasible, oxygen is not contained in the atmosphere because it will react to the solder layer blocking the needed eventual reaction with Sn in the solder. The deposition process continues until a thickness of about 0.1 to about 0.8 μm is obtained for the soldering layer 25.

Next, as shown in FIG. 2, an oxidation prevention (or, in some embodiments, an oxidation reducing) layer 30 can be formed on the soldering layer 25. The oxidation prevention layer 30 is formed to prevent the soldering layer 25 from being oxidized after the wafer is removed from a vacuum chamber. This oxygen prevention layer can contain any material that will prevent oxidation of the material used in the soldering layer 25. In some embodiments, the oxidation prevention layer 30 comprises Ag, Au, Pd, Cu, or combinations thereof. The oxidation prevention layer 30 can be formed using any deposition process, including an evaporator, CVD, or PVD until a thickness of about 0.01 to about 0.50 μm is obtained. In some embodiments, the oxidation prevention layer 30 can be deposited in an atmosphere containing negligible or no amounts of oxygen, such as an atmosphere containing Ar, He, Ne, inert gases, or combinations thereof.

Next, the substrate 10 (which is often in the form of a wafer) can be separated into individual dies by any known dicing process. Then, the individual dies are attached to a lead frame using any process known in the art. In some embodiments, the dies can be attached to the lead frame using a soldering process. In the soldering process, and as shown in FIG. 2, solder balls 35 are deposited on the oxidation prevention layer 30 by using any known process, including electroplating, printing through a mask, solder paste dot dispense or a ball drop process.

The solder balls 35 can be formed from any known solder material. In some embodiments, the solder balls can be formed with a die-attach solder such as eutectic Pb/Sn, high Pb/Sn or SnSb alloys, or a SAC solder. A SAC solder is an alloy of tin, silver, and copper. Typical formulations of SAC solders contain 3 to 4 wt % silver, 0.5 to 1.0 wt % copper, with the balance being tin. One formulation that can be used is SAC305, which contains 3 wt % silver, 0.5 wt % copper and 96.5% tin as the alloy.

The lead frame 40 can comprise any conductive material known in the art. In some embodiments, the lead frame 40 comprises Cu, Cu alloys, or Invar. Invar is a nickel-steel alloy notable for its uniquely low coefficient of thermal expansion. Invar typically has a formulation of Fe₆₄Ni₃₆.

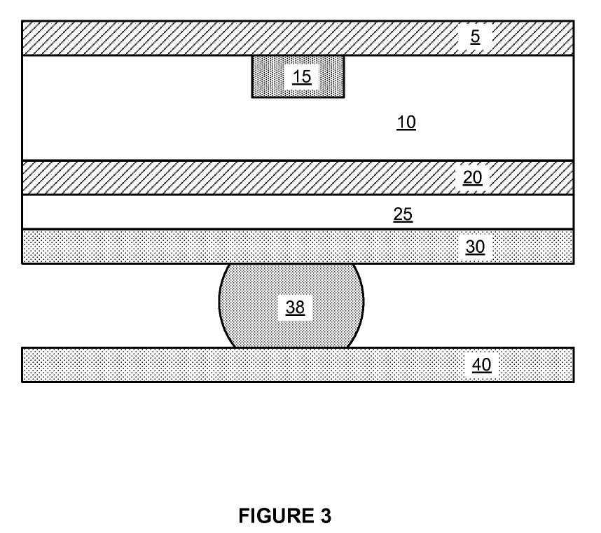

The lead frame 40 is connected to the solder balls 35 as known in the art. A reflow process is then performed to cause the solder balls 35 to partially react with the underlying metal layers and with the lead frame 40, in the process reflowing the metal in the solder into the shape of a bump 38. The resulting structure is depicted in FIG. 3. The current of such a structure flows vertically from the front of the structure, through the channel of the IC device 15, through the substrate 10, through the substrate backside contact, and then through the lead frame 40. The on-resistance (RDSₒₙ) of the structure comprises a function of the on-resistance that the current experiences in each of these regions: the combination of the RDSₒₙ in the channel, the substrate, the backside contact, and the package. The RDSₒₙ of the backside contact is typically small, but has become increasingly important as both the Si thickness in the substrate 10 and the die size reduces.

The resulting structure can then be encapsulated in any known molding material to make a semiconductor package, such as an epoxy molding compound, a thermoset resin, a thermoplastic material, or a potting material. The package can then be singulated using any process known in the art, including a saw singulation process or a water jet singulation process, or a laser-cut singulation method. Then, the singulated semiconductor packages may be electrically tested, taped, and reeled using any processes known in the art. The semiconductor packages can then be connected to a printed circuit board using any known connection (i.e., solder connectors) and used in any electronic device known in the art such as portable computers, disk drives, USB controllers, portable audio devices, or any other portable electronic devices.

The manufacturing methods and semiconductor devices described above have several features. First, the devices will exhibit a lower RDSₒₙ by approximately 0.1% to 10% (depending on die size and package configuration) because of the reduced drain contact resistance at the backside of the substrate. Second, TiNi materials—and especially Ti₄₉Ni₅₁—have approximately 100% lower electrical resistance than unsilicidized Ti or unsilicidized Ni layers by themselves, depending on the phase of the silicide. Third, less TiB is formed on the backside of the substrate because of the presence of Ni. The TiB formation can cause metal adhesion issues; thus, the device experiences less back metal peeling. Fourth, the TiNi layer is more ductile and less brittle than either Ti or Ni metal layers, leading to reduced fractures when parts are exposed to temperature cycling in normal on/off usage. Fifth, since the contact layer and the soldering layer can both be sputter deposited, the potential exists to combine the deposition of the contact layer with the deposition of the soldering layer in the same chamber, thereby enabling a single pass in the sputter deposition equipment to deposit both layers.

In some embodiments, the semiconductor device can be made by the method comprising: providing a silicon substrate containing an integrated circuit with a drain on the backside of the substrate; providing a contact layer containing TiNi on the backside of the substrate, the contact layer comprising a nickel silicide at the interface with the silicon substrate; providing a soldering layer on the contact layer; providing an oxidation reducing layer on the soldering layer; providing a solder on the oxidation prevention layer; and attaching a lead frame to the solder.

In other embodiments, the semiconductor device can be made by the method comprising: providing an integrated circuit in a silicon substrate so that the backside of the substrate comprises a drain; depositing a contact layer containing TiNi on a backside of the substrate; depositing a solderable metal layer on the contact layer; heating the resulting structure in a reduced oxygen atmosphere to form a nickel silicide at the interface of the contact layer and the silicon substrate; providing an oxidation reducing layer on the soldering layer; providing a solder on the oxidation reducing layer; and attaching a lead frame to the solder.

In still other embodiments, a contact layer for a semiconductor device can be made by the method comprising: providing an integrated circuit in a silicon substrate so that the backside of the substrate comprises a drain; depositing a contact layer containing TiNi on a backside of the substrate, wherein the TiNi material contains about 0.5 to about 95.5 wt % Ni and a thickness of about 0.01 to about 10 μm; heating the resulting structure in a reduced oxygen atmosphere to form a nickel silicide at the interface of the contact layer and the silicon substrate, the thickness of the nickel silicide ranging from about 0.01 to about 8 μm.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A semiconductor device, comprising:
a silicon substrate containing an integrated circuit with a drain on a backside of the substrate;
a contact layer containing TiNi contacting the drain on the backside, the contact layer comprising a nickel silicide at the interface with the silicon substrate;
a soldering layer on the contact layer;
an oxidation reducing layer on the soldering layer;
a solder bump on the oxidation prevention layer; and
a lead frame attached to the solder bump.

2. The device of claim 1, wherein the TiNi contact layer contains about 0.5 to about 95.5 wt % Ni.

3. The device of claim 1, wherein the TiNi contact layer contains about 50 to about 55.6 wt % Ni.

4. The device of claim 1, wherein the TiNi contact layer contains about 51 wt % Ni.

5. The device of claim 1, wherein the thickness of the contact layer can range from about 0.1 to about 10 μm.

6. The device of claim 1, wherein the thickness of the nickel silicide layer can range from about 0.1 to about 8 μm.

7. The device of claim 1, wherein the soldering layer comprises Ni, Ni₉₃V₇, Cu, Ni doped Si, or combinations thereof.

8. The device of claim 1, wherein the oxidation reducing layer comprises Ag, Au, Cu, Pd, Pt, or combinations thereof.

9. The device of claim 1, wherein the ratio of Ti to Ni in the contact layer can be adjusted to change the metal-induced wafer warpage of the substrate.

10. A DMOS semiconductor device, comprising:
a silicon substrate containing an integrated circuit with a drain on a backside of the substrate;
a nickel silicide layer on the backside, the thickness of the nickel silicide layer ranging from about 0.01 to about 8 μm;
a contact layer containing TiNi on the nickel silicide, the TiNi containing about 0.5 to about 95.5 wt % Ni and a thickness of about 0.01 to about 10 μm;
a soldering layer on the contact layer;
an oxidation reducing layer on the soldering layer;
a solder bump on the oxidation prevention layer; and
a lead frame attached to the solder bump.

11. The device of claim 10, wherein the thickness of the TiNi contact layer can range from about 0.1 to about 3 μm.

12. The device of claim 10, wherein the TiNi contact layer contains about 50 to about 55.6 wt % Ni.

13. The device of claim 10, wherein the TiNi contact layer contains about 51 wt % Ni.

14. The device of claim 10, wherein the soldering layer comprises Ni, Ni₉₃V₇, Cu, Si doped Ni, or combinations thereof.

15. The device of claim 10, wherein the oxidation reducing layer comprises Ag, Au, Cu, Pd, or combinations thereof.

16. The device of claim 10, wherein the ratio of Ti to Ni in the contact layer can be adjusted to change the metal-induced wafer warpage of the substrate.

17. The device of claim 10, wherein the thickness of the contact layer can range from about 0.1 to about 3 μm.

18. An electronic apparatus containing a semiconductor device, comprising:
a silicon substrate containing an integrated circuit with a drain on backside of the substrate;
a nickel silicide layer on the backside, the thickness of the nickel silicide layer ranging from about 0.01 to about 8 μm;
a contact layer containing TiNi on the nickel silicide, the TiNi containing about 0.5 to about 95.5 wt % Ni and a thickness of about 0.01 to about 10 μm;
a soldering layer on the contact layer;
an oxidation reducing layer on the soldering layer;
a solder bump on the oxidation prevention layer;
a lead frame attached to the solder bump, the lead frame further connected to a printed circuit board.

19. The apparatus of claim 18, wherein the TiNi contact layer contains about 50 to about 55.6 wt % Ni.

20. The apparatus of claim 18, wherein the TiNi contact layer contains about 51 wt % Ni.

21. The apparatus of claim 18, wherein the ratio of Ti to Ni in the contact layer can be adjusted to change the metal-induced wafer warpage of the substrate.

22. A contact layer for a silicon substrate containing an integrated circuit with a drain on a backside of the substrate, the contact layer comprising:
a nickel silicide layer at the interface with the backside of the silicon substrate, the thickness of the nickel silicide layer ranging from about 0.01 to about 8 μm; and
a TiNi layer on the nickel silicide, the TiNi layer containing about 0.5 to about 95.5 wt % Ni and a thickness of about 0.01 to about 10 μm.

23. The layer of claim 23, wherein the TiNi layer contains about 50 to about 55.6 wt % Ni.

24. The layer of claim 23, wherein the TiNi layer contains about 51 wt % Ni.

25. The layer of claim 23, wherein the thickness can range from about 0.1 to about 3 μm.
